(19) United States
(12) Patent Application Publication
(10) Pub. No.: US 2020/0185232 A1
(43) Pub. Date: Jun. 11, 2020

(54) GETTERING LAYER FORMING APPARATUS, GETTERING LAYER FORMING METHOD AND COMPUTER-READABLE RECORDING MEDIUM

(71) Applicant: Tokyo Electron Limited, Tokyo (JP)

(72) Inventor: Tetsuo FUKUOKA, Koshi City, Kumamoto (JP)

(21) Appl. No.: 16/617,536

(22) PCT Filed: May 21, 2018
(86) PCT No.: PCT/JP2018/019481

§ 371 Date: Nov. 27, 2019

(30) Foreign Application Priority Data
Jun. 1, 2017 (JP) 2017-109588

(51) Int. Cl. H01L 21/322; H01L 21/687; H01L 21/67; H01L 21/306; B24B 1/04

(52) U.S. Cl. CPC H01L 21/3221; H01L 21/68771; H01L 21/6708; H01L 21/67173; H01L 21/67288; H01L 21/30625; B24B 1/04; H01L 21/68764

(57) ABSTRACT

A gettering layer forming apparatus configured to form a gettering layer on a substrate includes a substrate holder configured to hold the substrate; a wrapping film configured to be brought into contact with the substrate held by the substrate holder and polish the substrate; a base configured to support the wrapping film, and configured to be moved in a vertical direction and rotated around a vertical axis; and a water supply configured to supply water onto the substrate held by the substrate holder.

### CROSS-REFERENCE TO RELATED APPLICATION

This application claims the benefit of Japanese Patent Application No. 2017-109588 filed on Jun. 1, 2017, the entire disclosures of which are incorporated herein by reference.

### TECHNICAL FIELD

The various aspects and embodiments described herein pertain generally to a gettering layer forming apparatus configured to form a gettering layer on a substrate, a gettering layer forming method using the gettering layer forming apparatus and a computer-readable recording medium.

### BACKGROUND

Recently, in a manufacturing process for a semiconductor device, a semiconductor wafer (hereinafter, simply referred to as “wafer”) having devices such as a plurality of electronic circuits formed on a front surface thereof is thinned by grinding and polishing a rear surface of the wafer.

If the rear surface of the wafer is ground (rough grinding and fine grinding), a damage layer including a crack or a flaw is formed on the rear surface of the wafer. Since the damage layer causes a residual stress on the wafer, a flexural strength of a chip obtained by dicing the wafer is weakened, resulting in breakage or flaw of the chip. Thus, to remove the damage layer, a stress relief processing is performed.

Meanwhile, to suppress metal contamination of copper or nickel on the devices on the front surface of the wafer, a gettering layer which captures the metal is formed on the rear surface of the wafer.

It is required to form the gettering layer while removing the damage layer by performing the stress relief processing.

For the formation of the gettering layer, various methods are conventionally used. For example, Patent Document 1 describes a method of forming the gettering layer on the rear surface of the wafer by performing a polishing processing such as dry polishing or CMP (Chemical Mechanical Polishing), an etching processing such as dry etching or wet etching, and an ion irradiation processing of irradiating a cluster ion of an inert gas.

### PRIOR ART DOCUMENT

Patent Docume1: Japanese Patent Laid-open Publication No. 2011-253983

### DISCLOSURE OF THE INVENTION

### Problems to be Solved by the Invention

In case of performing the dry polishing, the grinding (rough grinding and fine grinding) is performed in a wet environment, but the dry polishing is performed in a dry environment. Thus, after the grinding is performed, the wafer needs to be dried, which makes the processing complicated.

When performing the CMP, an alkaline chemical liquid is used as a slurry, and it is not easy to handle this alkaline chemical liquid, which also makes the processing complicated.

To perform the dry etching, the wafer needs to be dried after the grinding, the same as in the aforementioned case of performing the dry polishing. Furthermore, since the dry etching needs to be performed in a vacuum environment, an apparatus is scaled-up.

When performing the wet etching, it is not easy to manage a concentration and a temperature of a chemical liquid.

When performing the ion irradiation processing, the generation of the cluster ion and the irradiation of the cluster ion need to be performed separately, which complicates the processing. Further, the apparatus is also scaled-up.

In the conventional methods as mentioned above, there is still a room for improvement to form the gettering layer in a simple and easy way.

In view of the foregoing, exemplary embodiments provide a technique of forming a gettering layer on a rear surface of a substrate in a simple and easy way.

### Means For Solving The Problems

In one exemplary embodiment, a gettering layer forming apparatus configured to form a gettering layer on a substrate includes a substrate holder configured to hold the substrate; a wrapping film configured to be brought into contact with the substrate held by the substrate holder and polish the substrate; a base configured to support the wrapping film, and configured to be moved in a vertical direction and rotated around a vertical axis; and a water supply configured to supply water onto the substrate held by the substrate holder.

According to this exemplary embodiment, after the substrate is held by the substrate holder, the base and the wrapping film are placed near the substrate, and, then, the wrapping film is brought into contact with the substrate. Then, while supplying the water to the substrate from the water supply, the base is rotated, so that the substrate is polished by the wrapping film. At this time, since the water is supplied onto the substrate, a frictional heat due to the polishing can be suppressed, and polishing residues generated by the polishing can be removed to an outside of the substrate. In this way, the gettering layer forming apparatus according to the exemplary embodiment only needs the wrapping film, so an apparatus configuration can be simplified. Therefore, an apparatus cost can be reduced.

In another exemplary embodiment, there is provided a gettering layer forming method of forming a gettering layer on a substrate by using a gettering layer forming apparatus. Here, the gettering layer forming apparatus comprises a substrate holder configured to hold the substrate; a wrapping film configured to polish the substrate; a base configured to support the wrapping film, and configured to be moved in a vertical direction and rotated around a vertical axis; and a water supply configured to supply water to the substrate. Further, the gettering layer forming method comprises holding the substrate by the substrate holder and bringing the wrapping film into contact with the substrate; and rotating the base to thereby polish the substrate with the wrapping film while supplying the water to the substrate from the water supply.

In still another exemplary embodiment, there is provided a computer-readable recording medium having stored thereon computer-executable instructions that, in response to execution, cause a gettering layer forming apparatus to perform a gettering layer forming method of forming a gettering layer on a substrate.

### Effect of the Invention

According to the exemplary embodiments, it is possible to form the gettering layer on the rear surface of the wafer in a simple and easy way.

### BRIEF DESCRIPTION OF THE DRAWINGS

FIG. 1 is a plan view schematically illustrating a configuration of a substrate processing system including a gettering layer forming unit according to an exemplary embodiment.

FIG. 2 is a plan view illustrating a schematic configuration of a turntable.

FIG. 3 is a side view illustrating a schematic configuration of a processing apparatus.

FIG. 4 is an explanatory diagram illustrating a schematic configuration of a gettering layer forming unit according to a first exemplary embodiment.

FIG. 5A and FIG. 5B are explanatory diagrams illustrating an operation in which a wrapping film is brought into contact with a wafer in the first exemplary embodiment.

FIG. 6A and FIG. 6B are explanatory diagrams illustrating an operation in which the wrapping film is replaced in the first exemplary embodiment.

FIG. 7 is an explanatory diagram illustrating a schematic configuration of a gettering layer forming unit according to a second exemplary embodiment.

FIG. 8A and FIG. 8B are explanatory diagrams illustrating an operation in which a wrapping film is brought into contact with the wafer in the second exemplary embodiment.

FIG. 9 is an explanatory diagram illustrating a schematic configuration of the gettering layer forming unit according to the second exemplary embodiment.

FIG. 10 is an explanatory diagram illustrating a schematic configuration of a gettering layer forming unit according to a third exemplary embodiment.

FIG. 11A and FIG. 11B provide explanatory diagrams illustrating an operation in which a surface state of a wrapping film is inspected in the third exemplary embodiment.

FIG. 12A and FIG. 12B are explanatory diagrams illustrating the operation in which the surface state of the wrapping film is inspected in the third exemplary embodiment.

FIG. 13A and FIG. 13B are explanatory diagrams illustrating the operation in which the surface state of the wrapping film is inspected in the third exemplary embodiment.

FIG. 14A and FIG. 14B are explanatory diagrams illustrating the operation in which the surface state of the wrapping film is inspected in the third exemplary embodiment.

FIG. 15A and FIG. 15B are explanatory diagrams illustrating the operation in which the surface state of the wrapping film is inspected in the third exemplary embodiment.

FIG. 16 is an explanatory diagram illustrating an operation in which a light transmitter and a light receiver inspect the surface state of the wrapping film in the third exemplary embodiment.

FIG. 17 is an explanatory diagram illustrating an operation in which the light transmitter and the light receiver inspect the surface state of the wrapping film in the third exemplary embodiment.

FIG. 18 is an explanatory diagram illustrating a schematic configuration of a gettering layer forming unit according to a fourth exemplary embodiment.

FIG. 19 is an explanatory diagram illustrating a schematic configuration of a gettering layer forming unit according to a fifth exemplary embodiment.

FIG. 20 is an explanatory diagram illustrating a schematic configuration of the gettering layer forming unit according to the fifth exemplary embodiment.

FIG. 21 is an explanatory diagram illustrating a schematic configuration of a gettering layer forming unit according to a sixth exemplary embodiment.

FIG. 22 is a graph showing a relationship between a polishing water and a polishing amount.

### DETAILED DESCRIPTION

Hereinafter, exemplary embodiments will be described with reference to the accompanying drawings. In the specification and the drawings, parts having substantially same functions and configurations will be assigned same reference numerals, and redundant description thereof will be omitted.

<Substrate Processing System>

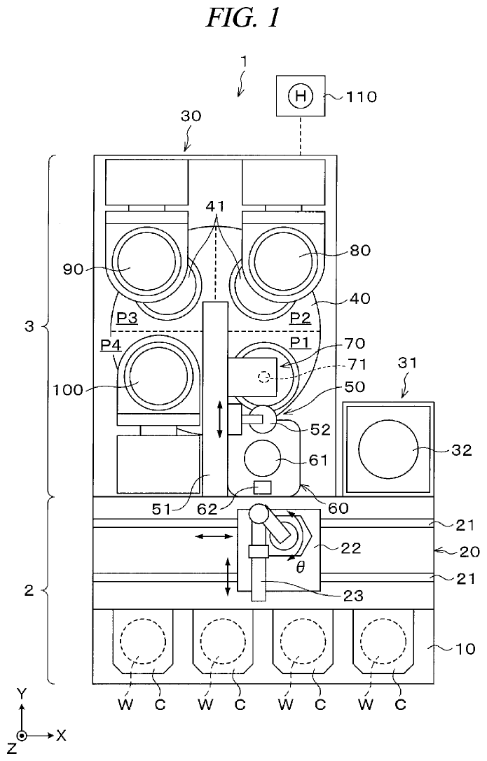

First, a configuration of a substrate processing system equipped with a gettering layer forming apparatus according to an exemplary embodiment will be described. FIG. 1 is a plan view schematically illustrating a configuration of a substrate processing system 1. In the following, in order to clarify positional relationships, the X-axis, Y-axis and Z-axis which are orthogonal to each other will be defined. The positive Z-axis direction will be regarded as a vertically upward direction.

In the substrate processing system 1 according to the present exemplary embodiment, a wafer W as a substrate is thinned. The wafer W is a semiconductor wafer such as, but not limited to, a silicon wafer or a compound semiconductor wafer. A device (not shown) is formed on a front surface of the wafer W, and a protective tape (not shown) for protecting the device is attached on the front surface. As preset processings such as grinding and polishing are performed on a rear surface of the wafer W, the wafer W is thinned.

The substrate processing system 1 includes a carry-in/out station 2 and a processing station 3 connected as a single body. The carry-in/out station 2 is configured to carry a cassette C, which accommodates therein a plurality of wafers W, to/from an outside. The processing station 3 is equipped with various kinds of processing apparatuses configured to perform preset processings on the wafer W.

The carry-in/out station 2 is equipped with a cassette placing table 10. In the shown example, the cassette placing table 10 is configured to be capable of holding a plurality of, for example, four cassettes C in a series in the X-axis direction.

Further, the carry-in/out station 2 includes a wafer transfer section 20 provided adjacent to the cassette placing table 10. A wafer transfer device 22 configured to be movable on a transfer path 21 extending in the X-direction is provided in the wafer transfer section 20. The wafer transfer device 22 is equipped with a transfer arm 23 configured to be movable in the horizontal direction and the vertical direction and pivotable around a horizontal axis and a vertical axis (θ direction), and is capable of transferring, with this transfer arm 23, the wafer W between the cassette C on each cassette placing plate 11 and apparatuses 30 and 31 of the processing station 3 to be described later. That is, the carry-in/out station 2 is configured to carry the wafer W into/from the processing station 3.

Within the processing station 3, the processing apparatus 30 configured to perform various processings such as grinding and polishing on the wafer W to thin the wafer W and the cleaning apparatus 31 configured to clean the wafer W processed by the processing apparatus 30 are arranged toward the positive X-axis direction from the negative X-axis direction.

The processing apparatus 30 includes a turntable 40, a transfer unit 50, an alignment unit 60, a cleaning unit 70, a rough grinding unit 80, a fine grinding unit 90 and a gettering layer forming unit 100 as a gettering layer forming apparatus.

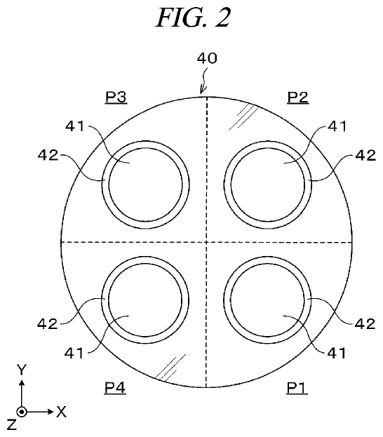

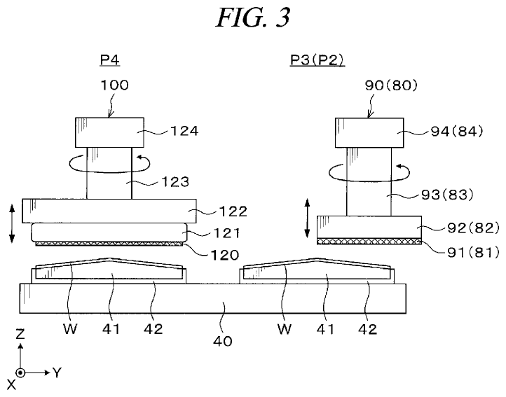

As depicted in FIG. 2 and FIG. 3, the turntable 40 is configured to be rotated by a rotating mechanism (not shown). Four chucks 41 as substrate holders each configured to attract and hold the wafer W are provided on the turntable 40. Each chuck 41 is held on a chuck table 42. The chuck 41 and the chuck table 42 are configured to be rotated by a rotating mechanism (not shown). Further, when viewed from the side, a front surface of the chuck 41, that is, a holding surface of the wafer W has a protruding shape with a central portion protruding higher than an end portion thereof. In a grinding processing (rough grinding and fine grinding), a ¼ arc portion of a grinding whetstone 81 (91) to be described later comes into contact with the wafer W. The front surface of the chuck 41 is formed to have the protruding shape and the wafer W is attracted to conform to this front surface of the chuck 41 so that the wafer W is ground in a uniform thickness.

The chucks 41 (chuck tables 42) are arranged on a circle concentric with the turntable 40 at a regular distance, that is, an angular distance of 90 degrees therebetween. The four chucks 41 can be moved to four processing positions P1 to P4 as the turntable 40 is rotated.

As shown in FIG. 1, in the present exemplary embodiment, the first processing position P1 is a position at a positive X-axis and negative Y-axis side of the turntable 40, and the cleaning unit 70 is disposed thereat. Further, the alignment unit 60 is disposed at a negative Y-axis side of the first processing position P1. The second processing position P2 is a position at a positive X-axis and positive Y-axis side of the turntable 40, and the rough grinding unit 80 is disposed thereat. The third processing position P3 is a position at a negative X-axis and positive Y-axis side of the turntable 40, and the fine grinding unit 90 is disposed thereat. The fourth processing position P4 is a position at a negative X-axis and negative Y-axis side of the turntable 40, and the gettering layer forming unit 100 is disposed thereat.

The transfer unit 50 is configured to be movable on a transfer path 51 extending in the Y-axis direction. The transfer unit 50 has a transfer arm 52 configured to be movable in the horizontal direction and the vertical direction and pivotable around a vertical axis (θdirection), and is capable of transferring the wafer W between the alignment unit 60 and the chuck 41 at the first processing position P1 with this transfer arm 52.

The alignment unit 60 is configured to adjust a direction of the wafer W before being processed in the horizontal direction. The alignment unit 60 is equipped with a spin chuck 61 configured to hold and rotate the wafer W; and a detector 62 configured to detect a notch of the wafer W. A position of the notch of the wafer W is detected by the detector 62 while the wafer W held by the spin chuck 61 is being rotated, and by adjusting the position of the notch, the direction of the wafer W in the horizontal direction is adjusted.

The cleaning unit 70 is configured to clean the rear surface of the wafer W. The cleaning unit 70 is disposed above the chuck 41, and is equipped with a nozzle 71 configured to supply a cleaning liquid, for example, pure water onto the rear surface of the wafer W. The cleaning liquid is supplied from the nozzle 71 while the wafer W held by the chuck 41 is being rotated. The supplied cleaning liquid is diffused on the rear surface of the wafer W, so that the rear surface is cleaned. Further, the cleaning unit 70 may further have a function of cleaning the chuck 41. In such a case, the cleaning unit 70 may be equipped with, for example, a nozzle (not shown) configured to supply the cleaning liquid to the chuck 41 and a stone (not shown) configured to come into contact with the chuck 41 and clean the chuck 41 physically.

The rough grinding unit 80 is configured to grind the rear surface of the wafer W roughly. As depicted in FIG. 3, the rough grinding unit 80 includes a base 82 and the grinding whetstone 81 supported at the base 82. The base 82 is connected to a driver 84 via a spindle 83. The driver 84 incorporates, for example, a motor (not shown), and is configured to move the grinding whetstone 81 and the base 82 in the vertical direction and rotate them. By respectively rotating the chuck 41 and the grinding whetstone 81 while keeping the wafer W held by the chuck 41 in contact with the ¼ arc portion of the whetstone 81, the rear surface of the wafer W is roughly ground. At this time, a grinding liquid, for example, water is supplied onto the rear surface of the wafer W. Further, in the present exemplary embodiment, though the grinding whetstone 81 is used as a grinding member for the rough grinding, the grinding member is not limited thereto. By way of non-limiting example, the grinding member may be a non-woven fabric containing abrasive grains, or the like.

The fine grinding unit 90 is configured to grind the rear surface of the wafer W finely. A configuration of the fine grinding unit 90 is substantially the same as the configuration of the rough grinding unit 80, and the find grinding unit 90 is equipped with the grinding whetstone 91, a base 92, a spindle 93 and a driver 94. Here, however, a particle size of the grinding whetstone 91 for the fine grinding is smaller than that of the grinding whetstone 91 for the rough grinding. By respectively rotating the chuck 41 and the grinding whetstone 91 while supplying the grinding liquid onto the rear surface of the wafer W held by the chuck 41 in the state that the rear surface of the wafer W is in contact with the ¼ arc portion of the grinding whetstone 91, the rear surface of the wafer W is ground. Like the grinding member for the rough grinding, the grinding member for the fine grinding is not limited to the grinding whetstone 81.

The gettering layer forming unit 100 is configured to form a gettering layer on the rear surface of the wafer W while removing, through a stress relief processing, a damage layer which is formed on the rear surface of the wafer W in the rough grinding and the fine grinding. A configuration of this gettering layer forming unit 100 will be explained later.

The cleaning apparatus 31 shown in FIG. 1 is configured to clean the rear surface of the wafer W which is ground and polished by the processing apparatus 30. To elaborate, while rotating the wafer W held by a spin chuck 32, a cleaning liquid, for example, pure water is supplied onto the rear surface of the wafer W. The supplied cleaning liquid is diffused on the rear surface of the wafer W, so that the rear surface is cleaned.

The above-described substrate processing system 1 includes a controller 110 as shown in FIG. 1. The controller 110 is, for example, a computer and includes a program storage (not shown). A program for controlling a processing performed on the wafer W in the substrate processing system 1 is stored in the program storage. Further, the program storage also stores therein a program for implementing wafer processings to be described later in the substrate processing system 1 by controlling the above-described various processing apparatuses and a driving system such as the transfer devices. Further, the programs may be recorded in a computer-readable recording medium H such as a hard disk (HD), a flexible disk (FD), a compact disk (CD), a magnet optical disk (MO) or a memory card, and may be installed from this recording medium H to the controller 110.

Now, the wafer processings performed by using the substrate processing system 1 having the above-described configuration will be explained. In the present exemplary embodiment, a protective film which protects a device is formed on the front surface of the wafer W.

First, the cassette C accommodating therein the wafers W is placed on the cassette placing table 10 of the carry-in/out station 2. To suppress deformation of the protective film, the wafer W is accommodated in the cassette C such that the front surface of the wafer W having the protective film attached thereon faces upwards.

Then, the wafer W is taken out from the cassette C by the wafer transfer device 22, and the taken wafer W is transferred into the processing apparatus 30 of the processing station 3. At this time, the front surface and the rear surface of the wafer W are inverted by the transfer arm 23 such that the rear surface of the wafer W faces upwards.

The wafer W transferred into the processing apparatus 30 is delivered onto the spin chuck 61 of the alignment unit 60. Then, the direction of the wafer W in the horizontal direction is adjusted by the alignment unit 60.

Subsequently, the wafer W is delivered onto the chuck 41 at the first processing position P1 by the transfer unit 50. Thereafter, by rotating the turntable 40 by 90 degrees in the counterclockwise direction, the chuck 41 is moved to the second processing position P2. Then, the rear surface of the wafer W is roughly ground by the rough grinding unit 80. A grinding amount by the rough grinding is set based on a thickness of the wafer W before being thinned and a required thickness of the wafer W after being thinned. At this time, a damage layer having a thickness of, e.g., 5 μm is formed on the rear surface of the wafer W.

Then, the turntable 40 is further rotated by 90 degrees in the counterclockwise direction, and the chuck 41 is moved to the third processing position P3. Then, the rear surface of the wafer W is finely ground by the fine grinding unit 90. At this time, the wafer W is ground to a thickness after being thinned, which is required as a product. Further, a damage layer having a thickness of, e.g., 0.5 μm is formed on the rear surface of the wafer W.

Thereafter, by further rotating the turntable 40 by 90 degrees in the counterclockwise direction, the chuck 41 is moved to the fourth processing position P4. Then, while performing the stress relief processing, a gettering layer is formed on the rear surface of the wafer W by the gettering layer forming unit 100. To be specific, the damage layer having the thickness of 0.5 μm after the fine grinding is ground to a thickness of, e.g., 0.09 μm, so that the gettering layer having a thickness of 0.09 μm is formed.

Afterwards, by further rotating the turntable 40 by 90 degrees in the counterclockwise direction or 270 degrees in the clockwise direction, the chuck 41 is moved to the first processing position P1. Then, the rear surface of the wafer W is cleaned by the cleaning liquid in the cleaning unit 70.

Subsequently, the wafer W is transferred into the cleaning apparatus 31 by the wafer transfer device 22. In the cleaning apparatus 31, the rear surface of the wafer W is cleaned by a cleaning liquid. The cleaning of the rear surface of the wafer W is also performed in the cleaning unit 70 of the processing apparatus 30. In the cleaning unit 70, however, a rotation speed of the wafer W is low, and the cleaning is performed to remove contaminants to some degree, for example, to the extent that the transfer arm 23 of the wafer transfer device 22 is not contaminated. Then, in the cleaning apparatus 31, the rear surface of this wafer W is further cleaned to a required degree of cleanness.

Then, the wafer W after being subjected to all the required processings is transferred back into the cassette C on the cassette placing table 10 by the wafer transfer device 22. In this way, a series of wafer processings in the substrate processing system 1 is ended.

According to the above-described exemplary embodiment, the rough grinding of the rear surface of the wafer W in the rough grinding unit 80, the fine grinding of the rear surface of the wafer W in the fine grinding unit 90, the formation of the gettering layer in the gettering layer forming unit 100 and the cleaning of the rear surface of the wafer W in the cleaning unit 70 and the cleaning apparatus 31 can be performed on the wafers W consecutively in the single substrate processing system 1. Thus, the wafers can be processed in the single substrate processing system 1 efficiently, so that a throughput can be improved.

### First Exemplary Embodiment

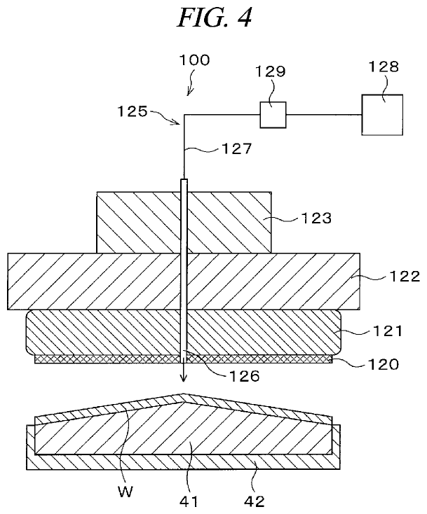

Now, a first exemplary embodiment of the gettering layer forming unit 100 will be discussed. As depicted in FIG. 3 and FIG. 4, the gettering layer forming unit 100 includes a wrapping film 120, a flexible member 121, a base 122, a spindle 123, a driver 124 and a water supply 125.

The wrapping film 120 and the flexible member 121 are supported at the base 122. The base 122 is connected to the driver 124 via the spindle 123. The driver 124 incorporates, for example, a motor (not shown), and is configured to move the wrapping film 120, the flexible member 121 and the base 122 in the vertical direction and rotate them.

The wrapping film 120 contains abrasive grains. The wrapping film 120 comes into contact with the wafer W, and is capable of polishing the wafer W. Further, the wrapping film 120 is thin and flexible. This wrapping film 120 has a size large enough to come into contact with the entire rear surface of the wafer W.

The flexible member 121 is made of a flexible material, for example, a resin. The flexible member 12 is provided on a top surface of the wrapping film 120 to cover the wrapping film 120. The wrapping film 120 and the flexible member 121 are stuck together by, for example, a double-sided tape or an adhesive.

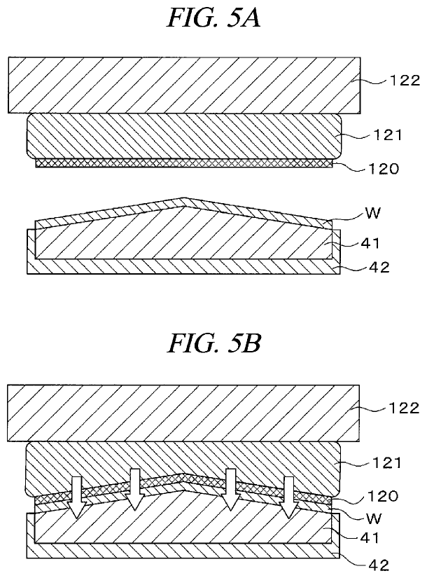

As shown in FIG. 5A, when the wrapping film 120 is not in contact with the wafer W, both the wrapping film 120 and the flexible member 121 are flat.

Meanwhile, as depicted in FIG. 5B, the wrapping film 120 is brought into contact with the wafer W. Here, due to various factors such as non-uniformity in roughness on the top surface of the chuck 41, non-uniformity in thickness of the protective film on the front surface of the wafer W and non-uniformity in roughness on the rear surface of the wafer W, a height position of the rear surface of the wafer W may not be uniform. Even if the non-uniformity in the height position exists, since the wrapping film 120 and the flexible member 200 have flexibility, bottom surfaces of the wrapping film 120 and the flexible member 121 are transformed to conform to a shape of the rear surface of the wafer W. Therefore, the wrapping film 120 can be brought into contact with the entire rear surface of the wafer W. Further, a pressure acting on the wrapping film 120 and the wafer W can be made uniform within the surface of the wafer W owing to the flexibility of the flexible member 200 (as indicated by arrows in FIG. 5B). Therefore, the polishing processing can be performed uniformly within the surface of the wafer W.

Further, in the present exemplary embodiment, the wrapping film 120 is brought into contact with the entire rear surface of the wafer W. However, a region of the wafer W which is contacted with the wrapping film 120 is not limited to the entire rear surface. By way of example, even in a case that the wrapping film 120 is brought into contact with a half of the rear surface of the wafer W, the wrapping film 120 can be made to be in contact with this half of the rear surface of the wafer W with a uniform pressure as the wrapping film 120 and the flexible member 121 have flexibility.

Furthermore, the above-described effect of bringing the wrapping film 120 into contact with the rear surface of the wafer W with the uniform pressure even when the height position of the rear surface of the wafer W is not uniform can be obtained regardless of the surface shape of the chuck 41. In the present exemplary embodiment, the surface of the chuck 41 has the protruding shape. However, even if the surface of the chuck 41 is flat, for example, the aforementioned effect can still be achieved.

In addition, in the present exemplary embodiment, since the chuck 41 has the protruding shape with the central portion protruding higher than the end portion thereof, the wafer W held by the chuck 41 also has a protruding shape. Thus, if a general hard polishing member is used, the polishing member may not come into contact with the entire rear surface of the wafer W, and the wafer W may not be polished uniformly within the surface thereof. In contrast, in the present exemplary embodiment, since the wrapping film 120 and the flexible member 121 have flexibility, the bottom surfaces of the wrapping film 120 and the flexible member 121 are transformed to conform to the protruding shape of the wafer W when the wrapping film 120 is brought into contact with the wafer W. Therefore, the wrapping film 120 can be brought into contact with the entire rear surface of the wafer W with the uniform pressure.

As shown in FIG. 4, the water supply 125 is configured to supply water onto the wafer W held by the chuck 41. The water supply 125 has a nozzle 126 through which the water (for example, pure water not containing slurry) is discharged. The nozzle 126 is provided at a central portion of the wrapping film 120. In the present exemplary embodiment, though only one nozzle 126 is provided at the central portion of the wrapping film 120, the number and the location of the nozzle 126 are not limited thereto. For example, a plurality of nozzles 126 may be provided at multiple positions within the surface of the wrapping film 120. Further, though the water is supplied onto the wafer W in the present exemplary embodiment, a mixture of the water and carbon dioxide may be supplied onto the wafer W in order to suppress static electricity in the grinding processing. Furthermore, besides the carbon dioxide, a microbubble or an ozone gas, for example, may be dissolved in the water, as will be described later.

Connected to the nozzle 126 is a supply line 127 through which the water is supplied to the nozzle 126. The supply line 127 penetrates, for example, the wrapping film 120, the flexible member 121, the base 122 and the spindle 123 and communicates with a water source 128 which stores the water therein. Further, the supply line 127 is equipped with a supply device group 129 including a flow rate controller and a valve configured to control a flow of the water.

In the gettering layer forming unit 100 having the above-described configuration, by respectively rotating the chuck 41 and the wrapping film 120 while keeping the wafer W held by the chuck 41 in contact with the wrapping film 120, the rear surface of the wafer W is polished. At this time, since the wrapping film 120 can be brought into contact with the entire rear surface of the wafer W with the uniform pressure, the polishing processing can be performed uniformly on the entire rear surface of the wafer W.

Further, since the wrapping film 120 is brought into contact with the entire rear surface of the wafer W, the polishing processing can be carried out in a short time period. Therefore, efficiency is improved. Here, a moving amount in the polishing processing is generally small, and it takes much time. Thus, carrying out the polishing processing in the short time period as in the present exemplary embodiment has advantages.

Furthermore, since the water is being supplied to the rear surface of the wafer W from the water supply 125, a frictional heat generated between the wrapping film 120 and the wafer W can be reduced by the water. Further, residues generated by the polishing can be removed to an outside of the wafer W by this water.

By performing the appropriate polishing processing as stated above, the damage layer having the thickness of 0.5 μm after the fine grinding can be removed to the thickness of 0.09 μm. Accordingly, the thinned wafer W is difficult to break, so that the reduction of the flexural strength can be suppressed. In addition, the gettering layer having the thickness of 0.09 μm can be formed appropriately, so that the metal contamination of the device on the front surface of the wafer W can be suppressed.

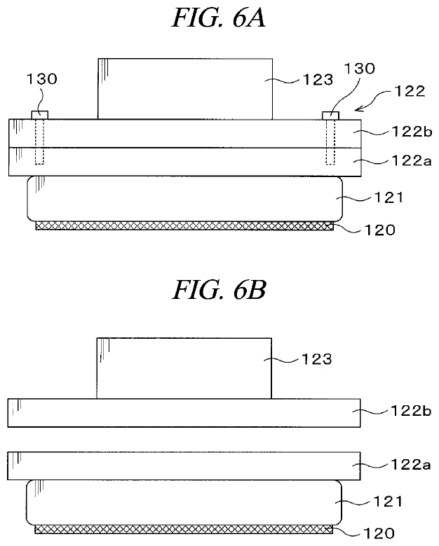

Here, a method of replacing the wrapping film 120 will be explained. As depicted in FIG. 6A and FIG. 6B, the base 122 is divided into a first base 122a at a lower side and a second base 122b at an upper side. The first base 122a supports the wrapping film 120 and the flexible member 121. As shown in FIG. 6A, the first base 122a and the second base 122b are connected by bolts 130. By removing the bolts 130 as illustrated in FIG. 6B, the first base 122a is separated from the second base 122b. In this way, by configuring the first base 122a to be attached to and detached from the second base 122b, it is possible to replace the wrapping film 120 and the flexible member 121 easily. Further, the method of replacing the wrapping film 120 is not limited to this example. By way of another example, the wrapping film 120 may be peeled off from the flexible member 121 to be replaced with a new one.

### Second Exemplary Embodiment

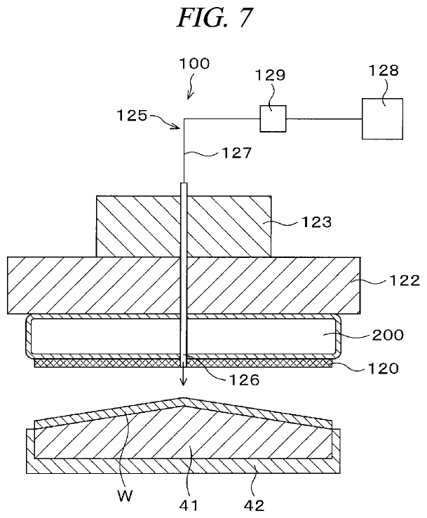

Now, a gettering layer forming unit 100 according to a second exemplary embodiment will be explained. The gettering layer forming unit 100 according to the second exemplary embodiment has a flexible member 200 filled with a fluid as shown in FIG. 7, instead of the flexible member 121 of the first exemplary embodiment. Various kinds of fluids such as water, oil and air may be used as the fluid charged in the flexible member 200. The other configuration of the gettering layer forming unit 100 according to the second exemplary embodiment is the same as the configuration of the gettering layer forming unit 100 according to the first exemplary embodiment.

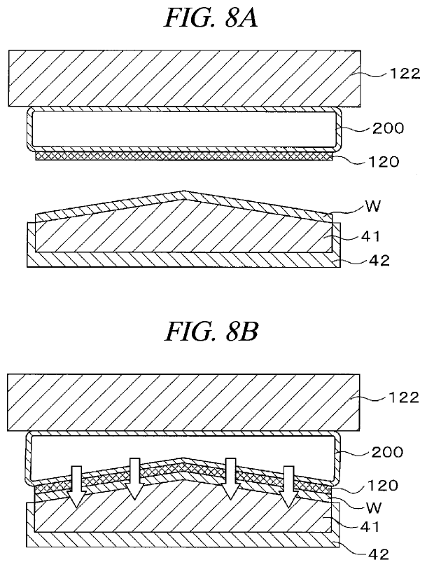

As shown in FIG. 8A, when a wrapping film 120 is not in contact with the wafer W, the wrapping film 120 and the flexible member 200 are flat.

Meanwhile, as illustrated in FIG. 8B, if the wrapping film 120 is brought into contact with the wafer W, bottom surfaces of the wrapping film 120 and the flexible member 121 are transformed to conform to the wafer W as the wrapping film 120 and the flexible member 200 have flexibility. Accordingly, the wrapping film 120 can be brought into contact with the entire rear surface of the wafer W. Furthermore, due to the flexibility of the flexible member 200, a pressure acting on the wrapping film 120 and the wafer W can be made to be uniform within the surface of the wafer (as indicated by arrows in FIG. 8B). Besides, in the present exemplary embodiment, the flexibility of the flexible member 200 is given by the fluid, so the degree of the flexibility thereof is very high. Therefore, the polishing processing can be performed more uniformly within the surface of the wafer W, so that it is possible to form the gettering layer appropriately while removing the damage layer on the rear surface of the wafer W appropriately.

Further, since the fluid is charged in the flexible member 200, a frictional heat generated between the wrapping film 120 and the wafer W can be suppressed from being transferred upwards from the flexible member 200. By way of example, if the frictional heat is transferred to a spindle 123 and the spindle 123 is thermally expanded, driving accuracy of a driver 124 may be deteriorated. In the present exemplary embodiment, however, the driver 124 can be appropriately driven due to the function of the flexible member 200.

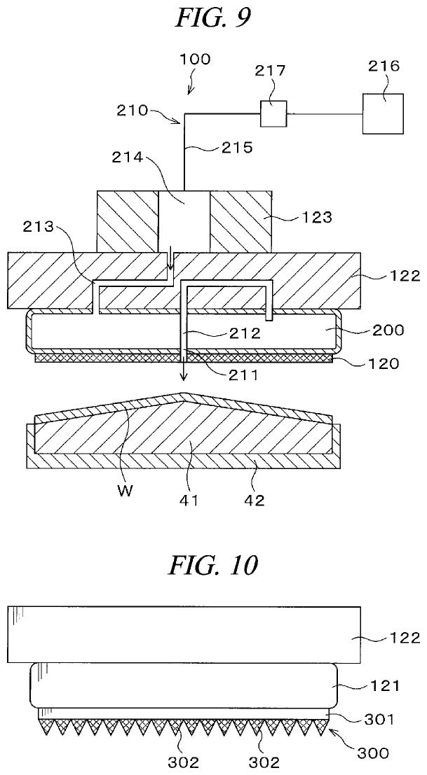

In the present exemplary embodiment, if the fluid charged in the flexible member 200 is water (hereinafter, sometimes referred to as “charging water”), this charging water and the water supplied to the wafer W in the polishing processing may be shared. In such a case, instead of the water supply 125 of the first exemplary embodiment, a water supply 210 is provided in the gettering layer forming unit 100, as illustrated in FIG. 9.

The water supply 210 is equipped with a nozzle 211 through which the water is discharged. The nozzle 211 is provided at a central portion of the wrapping film 120. Here, however, the number and the location of the nozzle 211 is not limited to this example. By way of example, a plurality of nozzles 211 may be provided at multiple positions within the surface of the wrapping film 120.

A supply line 212 through which the water is supplied to the nozzle 211 is connected to the nozzle 211. The supply line 212 communicates with the flexible member 200. A supply line 213 through which the water is supplied to the flexible member 200 is connected to the flexible member 200. The supply line 213 communicates with a water source 216 storing the water therein via a supply passageway 214 and a supply line 215. A diameter of the supply line 213 is smaller than a diameter of the supply passageway 214. Accordingly, a pressure which inflates the flexible member 200 can be applied. To apply the pressure to the inside of the flexible member 200 in this way, an orifice (not shown) may be provided at the supply line 213. Further, the supply line 215 may be equipped with a supply device group 217 including a flow rate controller and a valve configured to control a flow of the water.

When the polishing processing is performed, the water supplied from the water source 216 is sent into the nozzle 211 after being charged in the flexible member 200, and is supplied onto the wafer W from this nozzle 211.

In the present exemplary embodiment, a supply amount of the water may be controlled based on a water temperature within the flexible member 200. By way of example, the flexible member 200 may be equipped with a thermometer (not shown), and the water temperature within the flexible member 200 is measured by this thermometer. In case that the frictional heat generated between the wrapping film 120 and the wafer W during the polishing processing is large, the water temperature within the flexible member 200 is increased. In such a case, the supply amount of the water supplied from the nozzle 211 to the wafer W is increased. As a result, the frictional heat can be reduced, and the polishing processing can be performed appropriately.

Further, in the present exemplary embodiment, the supply amount of the water may be controlled based on a water pressure within the flexible member 200. By way of example, the flexible member 200 may be equipped with a pressure gauge (not shown), and an internal pressure of the flexible member 200 is measured by this pressure gauge. If the internal pressure of the flexible member 200 is varied when the wrapping film 120 is brought into contact with the wafer W in the polishing processing, the supply amount of the water into the flexible member 200 is controlled based on this variation. As a result, the pressure acting on the wrapping film 120 and the wafer W can be appropriately maintained, so that the polishing processing can be performed appropriately.

Moreover, in the present exemplary embodiment, a position of the base 122 in the vertical direction, that is, a moving amount of the base 122 in the vertical direction may be controlled based on the water pressure within the flexible member 200. The same as stated above, a pressure gauge (not shown), for example, may be provided at the flexible member 200 to measure the internal pressure of the flexible member 200. The moving amount (descending amount) of the base 122 in the vertical direction is controlled by the driver 124 based on the measurement result such that the pressure acting on the wrapping film 120 and the wafer W is maintained uniform within the surfaces of the wrapping film 120 and the wafer W. As a result, the polishing processing can be carried out appropriately.

### Third Exemplary Embodiment

Now, a gettering layer forming unit 100 according to a third exemplary embodiment will be described. The gettering layer forming unit 100 according to the third exemplary embodiment has a wrapping film 300 having irregularities on a surface thereof as shown in FIG. 10, instead of the wrapping film 120 of the first and second exemplary embodiments. The other configuration of the gettering layer forming unit 100 according to the third exemplary embodiment is the same as the configuration of the gettering layer forming unit 100 according to the first exemplary embodiment.

The wrapping film 300 has a film 301 and a plurality of protrusions 302 formed on a surface of the film 301. The protrusions 302 contain abrasive grains. Further, when viewed from the side, each protrusion 302 has a taper shape with a downwardly narrowing width. Though not particularly limited, a height of the protrusion 302 may be in a range from, e.g., 40 μm to 50 μm.

In this configuration, when the wrapping film 300 comes into contact with the wafer W in the polishing processing, polishing residues may be removed to an outside of the wafer W from gaps between the neighboring protrusions 302, that is, from recesses therebetween. Thus, the polishing processing can be performed more appropriately.

In the present exemplary embodiment, a surface state of the wrapping film 300 may be inspected. In the following, two inspection methods will be described.

A first inspection method will be explained. In the present inspection method, the surface state of the wrapping film 300 is inspected based on a load of a driver 124 which rotates the base 122 (wrapping film 300).

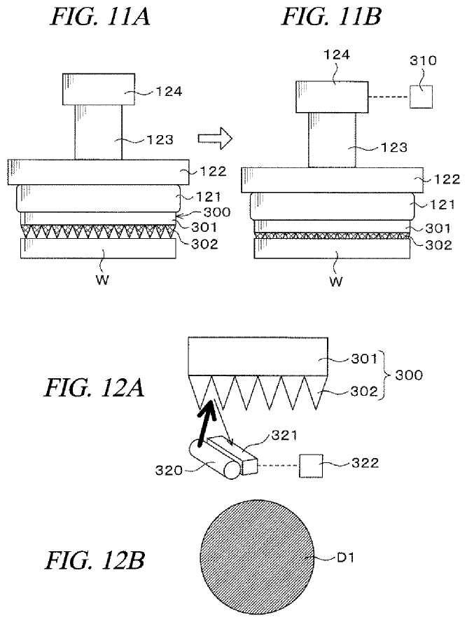

In this case, as shown in FIG. 11A and FIG. 11B, the gettering layer forming unit 100 is equipped with an inspector 310 provided at the driver 124. The inspector 310 is configured to detect a load of the driver 124, for example, a current value (torque) of a motor. At a time when the wrapping film 300 is begun to be used, the protrusions 302 are sharp, and a contact area between the protrusions 302 and the rear surface of the wafer W is small, as illustrated in FIG. 11A. Therefore, the load on the driver 124 is small, and the current value of the motor is low. Meanwhile, if the wrapping film 300 is used repeatedly, leading ends of the protrusions 302 are worn, and the contact area between the protrusions 302 and the rear surface of the wafer W is large, as shown in FIG. 11B. As a result, the load on the driver 124 is big, and the current value of the motor becomes high.

As stated above, by monitoring the current value of the motor of the driver 124, the surface state of the wrapping film 300 can be inspected. Further, if the current value of the motor of the driver 124 exceeds a preset threshold value, the wrapping film 300 may be replaced. Thus, an adequate time for replacing the wrapping film 300 can also be found out.

Now, a second inspection method will be explained. In the present inspection method, the surface state of the wrapping film 300 is optically inspected.

In this case, the gettering layer forming unit 100 includes, as illustrated in FIG. 12A and FIG. 12B, a light transmitter 320, a light receiver 321 and an inspector 322. The light transmitter 320 is configured to transmit light to the surface of the wrapping film 300. Though the kind of the light is not particularly limited, laser light may be used. The light receiver 321 is configured to receive light reflected on the surface of the wrapping film 300 after being transmitted from the light transmitter 320 (hereinafter, referred to as “reflection light”). The inspector 322 detects an intensity of the reflection light received by the light receiver 321 and inspects the surface state of the wrapping film 300 by performing an image processing of the intensity of the reflection light.

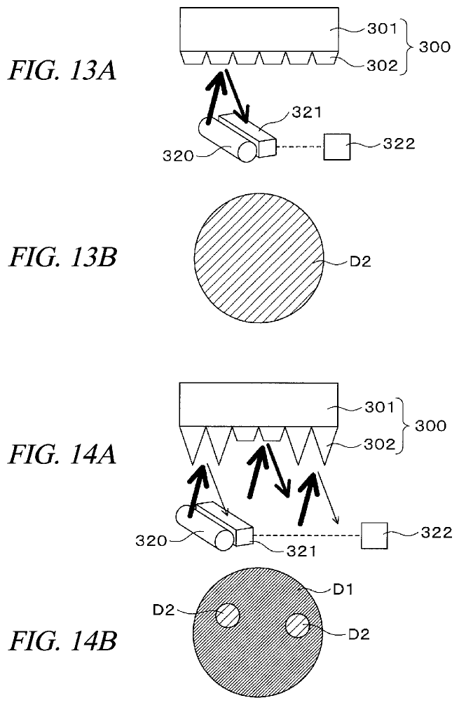

FIG. 12A and FIG. 12B illustrate a state when the use of the wrapping film 300 is begun, that is, when the leading ends of the protrusions 302 are not worn. FIG. 13A and FIG. 13B illustrate a state when the leading ends of the protrusions 302 are worn as the wrapping film 300 is used repeatedly. FIG. 12B and FIG. 13B provide images of an intensity distribution of the reflection light detected by the detector 322. On the images shown in FIG. 12B and FIG. 13B, dense halftone dots indicate a state where the image is dark and the intensity of the reflection light is low, and spares halftone dots indicate a state where the image is bright and the intensity of the reflection light is high.

As depicted in FIG. 12A, when the leading ends of the protrusions 302 are not worn out, a light reflection surface on the wrapping film 300 is small. Therefore, as shown in FIG. 12B, an intensity D1 of the reflection light is small. Meanwhile, when the leading ends of the protrusions 302 are worn as illustrated in FIG. 13A, the light reflection surface on the wrapping film 300 is large, and, thus, an intensity D2 of the reflection light is large, as shown in FIG. 13B. As stated above, by monitoring the intensity of the reflection light on the surface of the wrapping film 300, the surface state of the wrapping film 300 can be inspected. If the intensity of the reflection light exceeds a preset threshold value, the wrapping film 300 may be replaced. In this way, an adequate time for replacing the wrapping film 300 can also be found out.

Further, FIG. 14A and FIG. 14B illustrate a state where some of the protrusions 302 are worn out. That is, as compared to other protrusions 302 which are not worn and still sharp, leading ends of some of the protrusions 302 are worn and flat, as illustrated in FIG. 14A. In such a case, since the light reflection surface is small at portions where the protrusions 302 are not worn, an intensity D1 of the reflection light is small, whereas since the light reflection surface is large at portions where the protrusions 302 are worn, the intensity D2 of the reflection light is large, as shown in FIG. 14B. If the portions where the intensity of the reflection light is large and the portions where the intensity of the reflection light is small coexist, the quality of the wrapping film 300 is regarded as being poor. In this way, by inspecting the surface state of the wrapping film 300, good or bad quality of the wrapping film 300 can be detected. Furthermore, in case that the intensity of the reflection light is large at one side of the wrapping film 300 and small at the other side thereof, it may be expected that the wrapping film 300 is brought into contact with the wafer W in a non-uniform manner. In this way, a contact state between the wrapping film 300 and the wafer W can also be inspected.

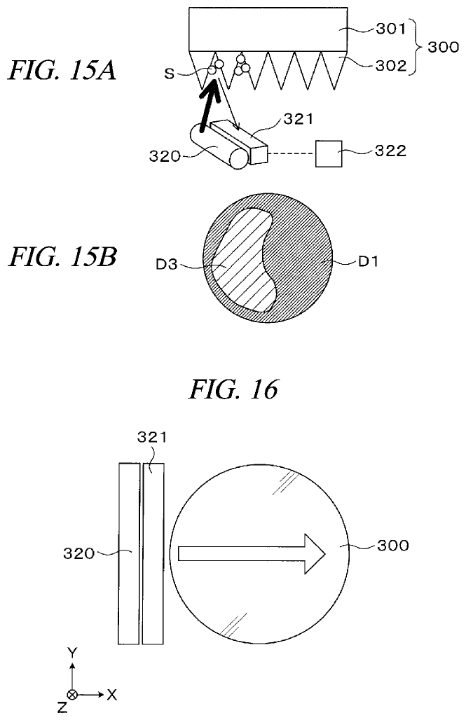

FIG. 15A and FIG. 15B illustrate a case where polishing residues S are left between the protrusions 302. That is, as shown in FIG. 15A, though the polishing residues S are not filled between some of the protrusions 302, the polishing residues S are filled between the other protrusions 302. In such a case, as shown in FIG. 15B, since the light reflection surface is small at a portion where the polishing residues S do not exist, the intensity D1 of the reflection light is small, whereas since the light reflection surface is large at a portion where the polishing residues S exist, an intensity D3 of the reflection light is large. In this way, if the portion where the intensity of the reflection light is large and the portion where the intensity of the reflection light is small coexist, it is possible to determine presence or absence of the polishing residues S on the wrapping film 300. In this way, by inspecting the surface state of the wrapping film 300, good or bad quality of the wrapping film 300 can be detected.

The size of the light reflection surface on the wrapping film 300 shown in FIG. 12A to FIG. 15B as described above increases in the order of the state where the protrusions 302 are not worn (sharp), the state where the protrusions 302 are worn (leading ends thereof are flat), and the state where the polishing residues S exist between the protrusions 302. Accordingly, the intensity of the reflection light increases in the order of D1, D2 and D3. By investigating these intensities D1, D2 and D2 in advance, the surface state of the wrapping film 300 can be detected.

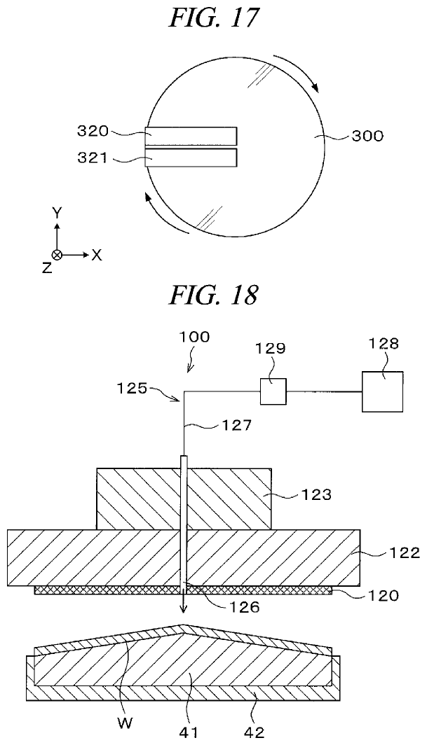

Further, in the present exemplary embodiment, regarding the way how the light transmitter 320 transmits the light to the entire surface of the wrapping film 300 and the light receiver 321 receives the reflection light, various kinds of methods can be used. By way of example, as shown in FIG. 16, each of the light transmitter 320 and the light receiver 321 may be longer than a diameter of the wrapping film 300 and to extend in the Y-axis direction. In such a case, as the light transmitter 320 and the light receiver 321 are moved in the X-axis direction as a single body, the entire surface of the wrapping film 300 can be inspected. Alternatively, as depicted in FIG. 17, each of the light transmitter 320 and the light receiver 321 may be longer than a radius of the wrapping film 300, and extend in the X-axis direction to be fixed. In such a case, as the wrapping film 300 is rotated, the light transmitter 320 and the light receiver 321 are capable of inspecting the entire surface of the wrapping film 300.

Moreover, in the present exemplary embodiment, the gettering layer forming unit 100 may be equipped with a device (not shown) configured to clean the protrusions 302, for example, a cleaning nozzle configured to supply a cleaning liquid to the protrusions 302. Through this cleaning device, cleanness of the protrusions 302 is maintained, and a polishing effect of the wrapping film 300 can be maintained. In this case, the protrusions 302 may be cleaned by the cleaning device provided near the peripheral portion of the wafer W at the same time as the polishing processing for the wafer W by the wrapping film 300 is performed. In this way, by performing the polishing processing and the cleaning processing at the same time, the processing time can be shortened.

### Fourth Exemplary Embodiment

In the gettering layer forming unit 100 according to the first to third exemplary embodiments as described above, the flexible member 121 may be omitted. FIG. 18 illustrates a schematic configuration of a gettering layer forming unit 100 according to a fourth exemplary embodiment. Specifically, the gettering layer forming unit 100 according to the fourth exemplary embodiment is prepared by removing the flexible member 121 from the gettering layer forming unit 100 of the first exemplary embodiment. In this configuration, a wrapping film 120 is directly supported at a base 122.

Even if the flexible member 121 is not provided as in the present exemplary embodiment, by respectively rotating a chuck 41 and the wrapping film 120 while keeping the wafer W held by the chuck 41 in contact with the wrapping film 120, the rear surface of the wafer W can be appropriately polished. Further, since the apparatus configuration can be simplified, the apparatus cost can be reduced.

### Fifth Exemplary Embodiment

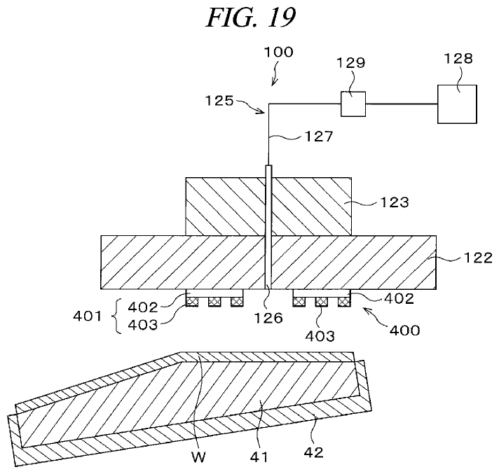

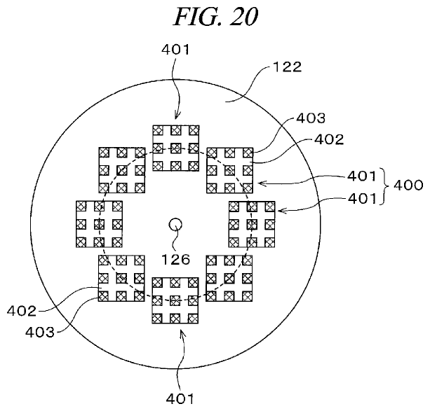

Now, a gettering layer forming unit 100 according to a fifth exemplary embodiment will be explained. The gettering layer forming unit 100 according to the fifth exemplary embodiment includes a wrapping film 400 shown in FIG. 19 and FIG. 20, instead of the wrapping film 120 of the fourth exemplary embodiment exemplary embodiment. The other configuration of the gettering layer forming unit 100 according to the fifth exemplary embodiment is the same as the configuration of the gettering layer forming unit 100 of the fourth exemplary embodiment. In the fifth exemplary embodiment, however, a chuck 41 and a chuck table 42 are configured such that inclinations thereof are adjustable. In the shown example, the inclinations of the 41 and the chuck table 42 are adjusted such that the rear surface of the wafer W is parallel to the wrapping film 400.

The wrapping film 400 includes a plurality of film bodies 401 supported at a base 122. By way of example, the film bodies 401 are arranged at a regular distance therebetween on a circle concentric with the base 122. However, the layout of the film bodies 401 with respect to the base 122 is not limited to the shown example, and the film bodies 401 may be arranged on multiple concentric circles. That is, these film bodies 401 may be arranged on two or more concentric circles.

Each film body 401 is equipped with a film 402 having, for example, a rectangular shape when viewed from the top; and a plurality of protrusions 403 formed on a surface of the film 402. The protrusions 403 contain abrasive grains. Further, each protrusion 403 has a rectangular parallelepiped shape. Further, in a plan view, a shape of the film 402 in the film body 401 is not particularly limited, for example, the film 402 may have a circular shape. Furthermore, the number and the layout of the protrusions 403 on the film 402 are not particularly limited. A shape of the protrusion 403 is not particularly limited as long as it has a columnar shape. For example, the protrusion 403 may have a cylinder shape or a trigonal prism shape.

In this configuration, when the wrapping film 400 is brought into contact with the wafer W in the polishing processing, the protrusions 403 come into contact with the wafer W while being spaced apart from the wafer W. Accordingly, polishing residues generated in the polishing processing can be removed to an outside of the wafer W through the gaps between the protrusions 403 and gaps between the film bodies 401. Further, since the gaps are provided between the protrusions 403 and between the film bodies 401, water supplied from a nozzle 126 can be removed out from these gaps, so that water removing property can be improved. Therefore, the polishing processing can be carried out more appropriately.

Moreover, in the present exemplary embodiment, since the protrusions 403 have the rectangular parallelepiped shape (columnar shape), a contact area between the protrusions 403 and the wafer W does not change even if leading ends of the protrusions 403 are worn. Thus, a contact pressure (surface pressure) of the protrusions 403 upon the wafer W can be maintained, so that a load on a driver 124 can be maintained constant. As a result, the polishing processing can be performed more appropriately.

### Sixth Exemplary Embodiment

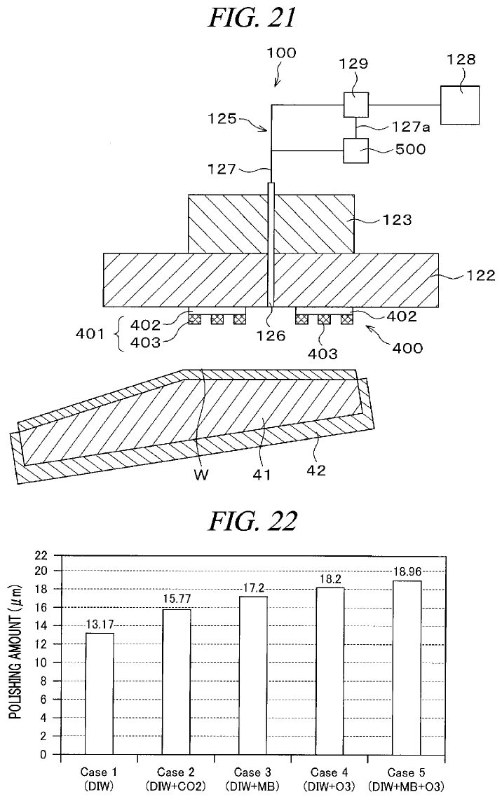

In the gettering layer forming unit 100 according to the first to fifth exemplary embodiments as described above, the water supplied from the water supply 125 may not be limited to the pure water. For example, a microbubble may be dissolved in the wafer supplied from the water supply 125. FIG. 21 illustrates a schematic configuration of a gettering layer forming unit 100 according to a sixth exemplary embodiment. In the gettering layer forming unit 100 according to the sixth exemplary embodiment, a water supply 125 supplies the water in which the microbubble is dissolved in the gettering layer forming unit 100 of the fifth exemplary embodiment. Further, the other configuration of the gettering layer forming unit 100 according to the sixth exemplary embodiment is the same as the configuration of the gettering layer forming unit 100 of the fifth exemplary embodiment.

The water supply 125 is equipped with a generator 500 configured to dissolve the microbubble in the pure water. The generator 500 generates the microbubble and dissolves the generated microbubble in the flown pure water. A configuration of the generator 500 is not particularly limited, and a commonly known device may be used. Furthermore, the generator 500 is provided at a bypass line 127a which bypasses from a supply device group 129 at a supply line 127.

In the water supply 125, the pure water supplied from a water source 128 flows to the bypass line 127a through the supply device group 129, and the microbubble is dissolved in this pure water while the pure water passes through the generator 500. Then, the water in which the microbubble is dissolved is supplied from a nozzle 126 via the supply line 127.

If the water in which the microbubble is dissolved is supplied to the wafer W, polishing residues generated in the polishing processing is easily removed to an outside of the wafer W by the water. Accordingly, even if a contact pressure of the wrapping film 400 upon the wafer W in the polishing processing is maintained same, a polishing amount can be increased, so that efficiency of the polishing processing can be improved.

Further, the water other than the pure water, which is supplied from the water supply 125, is not limited to the water in which the microbubble is dissolved. By way of example, an ozone gas may be dissolved in the water, or both the microbubble and the ozone gas may be dissolved in the water. Further, carbon dioxide may be dissolved in the water. In any cases, the efficiency of the polishing processing can be improved as stated above.

Here, an effect of improving the efficiency of the polishing processing will be explained. As shown in FIG. 22, the inventors have conducted an experiment for five cases. A vertical axis of FIG. 22 indicates a polishing amount of silicon per preset time. Case 1 is a comparative example where the pure water (DIW in FIG. 22) is used. Case 2 is an example where the water in which the carbon dioxide (CO₂ in FIG. 22) is dissolved is used. Case 3 is an example where the water in which the microbubble (MB in FIG. 22) is dissolved is used. Case 4 is an example where the water in which the ozone gas (O₃ in FIG. 22) is dissolved is used. Case 5 is an example where the water in which both the microbubble and the ozone gas are dissolved is used. As can be seen from FIG. 22, the polishing amounts are found to be increased in the cases 2 to 5, as compared to the case 1 where the pure water is used. From this experiment, it is found out that the efficiency of the polishing processing is improved if the microbubble, the ozone gas, the carbon dioxide or the like is dissolved in the pure water.

Further, in the present exemplary embodiment, if the pure water supplied from the water source 128 does not flow to the bypass line 271a through the supply device group 129 but flows directly into the supply line 127, the pure water in which no microbubble is dissolved is supplied from the nozzle 126. In this way, the water supply 125 of the present exemplary embodiment is capable of selectively supplying either the pure water or the water in which the microbubble is dissolved.

The water in which the microbubble is dissolved may be supplied to the wafer W from the water supply 125 during the polishing processing, for example, and the pure water may be supplied to the wafer W from the water supply 125 after the polishing processing, for example, in the cleaning processing. As stated above, by using the pure water and the water in which the microbubble is dissolved while switching them, the efficiency of the polishing processing can be further improved.

Moreover, in the water supply 125 according to the fifth exemplary embodiment and the sixth exemplary embodiment, the nozzle 126 is disposed to supply the water to the central portion of the wafer W. However, the number and the layout of the nozzle 126 are not limited thereto. By way of example, the nozzle 126 may be disposed to supply the water to the peripheral portion of the wafer W.

### Other Exemplary Embodiments

In the above-described exemplary embodiments, the gettering layer forming unit 100 is provided within the processing apparatus 30. However, a gettering layer forming apparatus (not shown) having the same configuration as that of the gettering layer forming unit 100 may be provided at an outside of the processing apparatus 30. In such a case, the same effect as obtained in the above-described exemplary embodiments can be achieved.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting. The scope of the inventive concept is defined by the following claims and their equivalents rather than by the detailed description of the exemplary embodiments. It shall be understood that all modifications and embodiments conceived from the meaning and scope of the claims and their equivalents are included in the scope of the inventive concept.

### EXPLANATION OF CODES

1: Substrate processing system

30: Processing apparatus

31: Cleaning apparatus

40: Turntable

41: Chuck

50: Transfer unit

60: Alignment unit

70: Cleaning unit

80: Rough grinding unit

90: Fine grinding unit

100: Gettering layer forming unit

110: Controller

120: Wrapping film

121: Flexible member

122: Base

122a: First base

122b: Second base

123: Spindle

124: Driver

125: Water supply

200: Flexible member

210: Water supply

300: Wrapping film

301: Film

302: Protrusion

310: Inspector

320: Light transmitter

321: Light receiver

322: Inspector

400: Wrapping film

401: Film body

402: Film

403: Protrusion

500: Generator

W: Wafer

1. A gettering layer forming apparatus configured to form a gettering layer on a substrate, the gettering layer forming apparatus comprising:
a substrate holder configured to hold the substrate;
a wrapping film configured to be brought into contact with the substrate held by the substrate holder and polish the substrate;
a base configured to support the wrapping film, and configured to be moved in a vertical direction and rotated around a vertical axis; and
a water supply configured to supply water onto the substrate held by the substrate holder.

2. The gettering layer forming apparatus of claim 1,
wherein multiple protrusions are formed on a surface of the wrapping film, and
the protrusions are brought into contact with the substrate while gaps are maintained between the protrusions.

3. The gettering layer forming apparatus of claim 2,
wherein each protrusion has a columnar shape.

4. The gettering layer forming apparatus of claim 1,
wherein the wrapping film is brought into contact with an entire surface of the substrate.

5. The gettering layer forming apparatus of claim 1, further comprising:
a flexible member, having flexibility, disposed to cover the wrapping film.

6. The gettering layer forming apparatus of claim 1,
wherein multiple protrusions each having a narrowing width toward the substrate holder when viewed from a side are formed on a surface of the wrapping film.

7. The gettering layer forming apparatus of claim 6, further comprising:
a driver configured to rotate the base; and
an inspector configured to inspect a surface state of the wrapping film based on a load of the driver.

8. The gettering layer forming apparatus of claim 6, further comprising:
a light transmitter configured to transmit light to the surface of the wrapping film;
a light receiver configured to receive light reflected from the surface of the wrapping film; and
an inspector configured to inspect a surface state of the wrapping film based on an intensity of the light received by the light receiver.

9. The gettering layer forming apparatus of claim 1,
wherein the base is divided into a first base and a second base, and
the first base is configured to support the wrapping film and is attached to the second base in a detachable manner.

10. The gettering layer forming apparatus of claim 1,
wherein the water supply supplies water in which at least a microbubble or an ozone gas is dissolved.

11. The gettering layer forming apparatus of claim 10,
wherein the water supply selectively supplies the water in which at least the microbubble or the ozone gas is dissolved and water in which both the microbubble and the ozone gas are not dissolved.

12. A gettering layer forming method of forming a gettering layer on a substrate by using a gettering layer forming apparatus,
wherein the gettering layer forming apparatus comprises:
a substrate holder configured to hold the substrate;
a wrapping film configured to polish the substrate;
a base configured to support the wrapping film, and configured to be moved in a vertical direction and rotated around a vertical axis; and
a water supply configured to supply water to the substrate, and
wherein the gettering layer forming method comprises:
holding the substrate by the substrate holder and bringing the wrapping film into contact with the substrate; and
rotating the base to thereby polish the substrate with the wrapping film while supplying the water to the substrate from the water supply.

13. The gettering layer forming method of claim 12,
wherein multiple protrusions each having columnar shape are formed on a surface of the wrapping film, and
the protrusions are brought into contact with the substrate while gaps are maintained between the protrusions.

14. The gettering layer forming method of claim 12,
wherein the wrapping film is brought into contact with an entire surface of the substrate.

15. The gettering layer forming method of claim 12,
wherein a flexible member, having flexibility, disposed to cover the wrapping film is provided.

16. The gettering layer forming method of claim 12,
wherein multiple protrusions each having a narrowing width toward the substrate holder when viewed from a side are formed on a surface of the wrapping film.

17. The gettering layer forming method of claim 12,
wherein water in which at least a microbubble or an ozone gas is dissolved is supplied to the substrate from the water supply while polishing the substrate, and
water in which both the microbubble and the ozone gas are not dissolved is supplied to the substrate from the water supply after polishing the substrate.

18. A computer-readable recording medium having stored thereon computer-executable instructions that, in response to execution, cause a gettering layer forming apparatus to perform a gettering layer forming method of forming a gettering layer on a substrate,
wherein the gettering layer forming apparatus comprises:
a substrate holder configured to hold the substrate;
a wrapping film configured to polish the substrate;
a base configured to support the wrapping film, and configured to be moved in a vertical direction and rotated around a vertical axis; and
a water supply configured to supply water to the substrate, and
wherein the gettering layer forming method comprises:
holding the substrate by the substrate holder and bringing the wrapping film into contact with the substrate; and
rotating the base to thereby polish the substrate with the wrapping film while supplying the water to the substrate from the water supply.
